(19) United States
(12) Patent Application Publication
(10) Pub. No.: US 2006/0125111 A1
(43) Pub. Date: Jun. 15, 2006

(54) Flip chip device

(76) Inventors: Wen-Chih Chen, Hsin Chu Hsien (TW); Sheng-Shu Yang, Hsin Chu City (TW)

Correspondence Address: RABIN & BERDO, P.C., Suite 500, 1101 14 Street, Washington, DC, 20005, US

(21) Appl. No.: 11/094,198

(22) Filed: Mar. 31, 2005

(30) Foreign Application Priority Data
Dec. 14, 2004 (TW) 93138755

(51) Int. Cl. H01L 23/48

(52) U.S. Cl. 257/778

(57) ABSTRACT

A flip chip device made using LCD-COG (liquid crystal display-chip on glass) technique. The flip chip device comprises a substrate, a plurality of chips having surfaces with a plurality of compliant bumps thereon. The compliant bumps are centrally disposed in the center of the chips for electrically connecting the chips and the substrate. An adhesive is daubed on a joint area of the substrate and the chips for jointing the substrate and the chips. By changing the position of the compliant bumps so that they are centrally disposed on the chips without changing the electrical characteristics and the wiring arrangement of the chips, costs are lowered, reliability is increased and the glass substrate is less easily bent.

### BACKGROUND OF THE INVENTION

1. Field of the Invention

The present invention relates to a flip chip device, and more particularly to a flip chip device using a LCD-COG (liquid crystal display-chip on glass) technique.

2. Description of the Prior Art

In flip chip technology the jointed surface of the chip and the substrate form a pad or bump replacing the lead frame used in wire bonding technology. By directly stressing the bump or pad of the jointed surface of the chip and the substrate, electric conduction of the circuit is achieved. Recently, due to advances in the related technology, electronic products are becoming increasingly smaller and lightweight, so the applications of flip chip technology are increasing day by day.

The flip chip device of the prior art is the surface of the chip and the bumps formed by the substrate; the surface of the substrate is daubed with an adhesive and then the chip and the substrate are stressed to complete the flip chip device. Because the thermal expansion coefficient of the chip is different from that of the glass substrate, it may result in a certain degree of warp causing a disproportionate gap in the center and on the edge of the IC chip.

In order to improve upon the above stated disadvantages, U.S. Pat. No. 5,508,228 discloses “compliant electrically connective bumps for an adhesive flip chip integrated circuit device and methods for forming same”. As shown in FIG. 1, a compliant bump includes an IC chip 10, a compliant bump 14 covering a metal layer 16 thereon is formed on a bond pad 12 and connected to glass base 18.

FIG. 2 shows ROC Patent No. 200402859 that discloses “Bump structure and method of making”. A compliant bump includes an IC chip 20 with a plurality of conductive joints 22 and a protective film 26 covering the joints 22, and a compliant bump 28. The compliant bump 28 is formed with a lower metal layer 23, a polymer bump 21, an upper metal layer 24 and a metal layer 25.

However, due to the limits of the initial arrangement of the IC, regardless of whether gold bumps or compliant bumps are used, these bumps will always have a ringed-type arrangement. FIG. 3 shows a plurality of bumps 31 ringed around an IC chip 30. This arrangement may however, have a bad effect when applied to the COG junction. As shown in FIG. 4, which is a schematic view of a warped COG of the flip chip device due to the thermal applied force of the prior art. The IC chip 34 and the substrate 35 are jointed via the bumps 36 and the conductive adhesive 37 (as the anisotropic conductive film). Because the thermal expansion coefficient of the IC chip 34 is different from that of the glass substrate 35, it causes a certain degree of warp creating a disproportionate gap in the center and on the edge of the IC chip thereby reducing the reliability of the products.

The inventor of the present invention recognizes the above shortage should be corrected and special effort has been paid to research this field. The present invention is presented with reasonable design and good effect to resolve the above problems.

### SUMMARY OF THE INVENTION

The prime objective of the present invention provides a flip chip device to centrally dispose the bumps on the center of chips reduce costs, increase their reliability and reduce bending.

For achieving the objectives stated above, a flip chip device comprises a substrate, a plurality of chips having surfaces and a plurality of compliant bumps thereon, the compliant bumps are centrally disposed on the center of the chips for electrically connecting the chips and the substrate; and an adhesive daubed on a joint area of the substrate and the chips for jointing the substrate and the chips. The compliant bumps are formed with a lower metal layer, a bump and a upper metal layer; the upper metal layer covers two opposite side surfaces of the bump to connect with the lower metal layer for electrically connecting the substrate and the chips, and another two opposite side surfaces that do not cover the metal layer that blocks the lateral electrical connection of the adjacent compliant bumps so as to ensure the compliant bumps centrally disposed on the center of the chips will not short. By extending the lower metal layer to change the position of the compliant bumps, the compliant bumps are disposed on the center of the chips without changing the electrical characteristics or the wiring arrangement of the chips.

The flip chip device further comprises a plurality of non-connecting electrically compliant bumps disposed in a corner of the chip for maintaining the parallel of the joint.

It is to be understood that both the foregoing general description and the following detailed description are exemplary, and are intended to provide further explanation of the invention as claimed. Other advantages and features of the invention will be apparent from the following description, drawings and claims.

### BRIEF DESCRIPTION OF THE DRAWINGS

FIG. 1 is a schematic view showing the structure of the conductive compliant bump of the prior art;

FIG. 2 is another schematic view showing a conductive compliant bump structure of the prior art;

FIG. 3 is a schematic view showing the arrangement of the compliant bumps of the prior art;

FIG. 4 is a schematic view showing the warped COG of the flip chip device due to the thermal applied force of the prior art;

FIG. 5 is a schematic view showing the structure of the flip chip device of the present invention;

FIG. 6A and FIG. 6B are schematic views showing the structures of the compliant bumps of the present invention;

FIG. 7 is a schematic view showing the second embodiment of the compliant bumps disposed on the chip of the present invention;

FIG. 8A is a schematic view showing the third embodiment of the compliant bumps disposed on the chip of the present invention;

FIG. 8B is a schematic view showing the fourth embodiment of the compliant bumps disposed on the chip of the present invention;

FIG. 9A is a schematic view showing the fifth embodiment of the compliant bumps disposed on the chip of the present invention;

FIG. 9B is a schematic view showing the sixth embodiment of the compliant bumps disposed on the chip of the present invention;

FIG. 10 A is a schematic view showing the seventh embodiment of the compliant bumps disposed on the chip of the present invention;

FIG. 10B is a schematic view showing the eighth embodiment of the compliant bumps disposed on the chip of the present invention;

FIG. 11A is a schematic view showing the ninth embodiment of the compliant bumps disposed on the chip of the present invention; and

FIG. 11B is a schematic view showing the tenth embodiment of the compliant bumps disposed on the chip of the present invention.

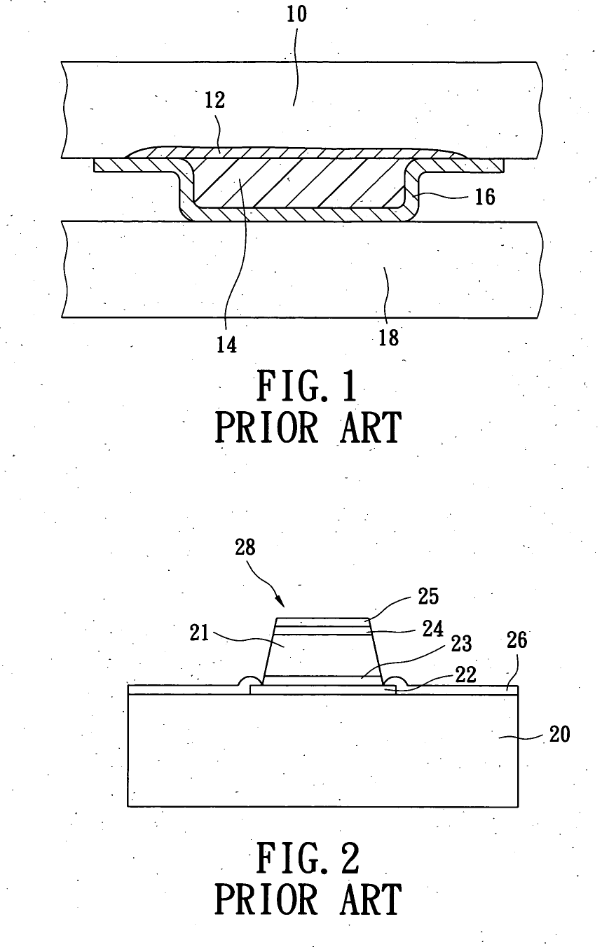

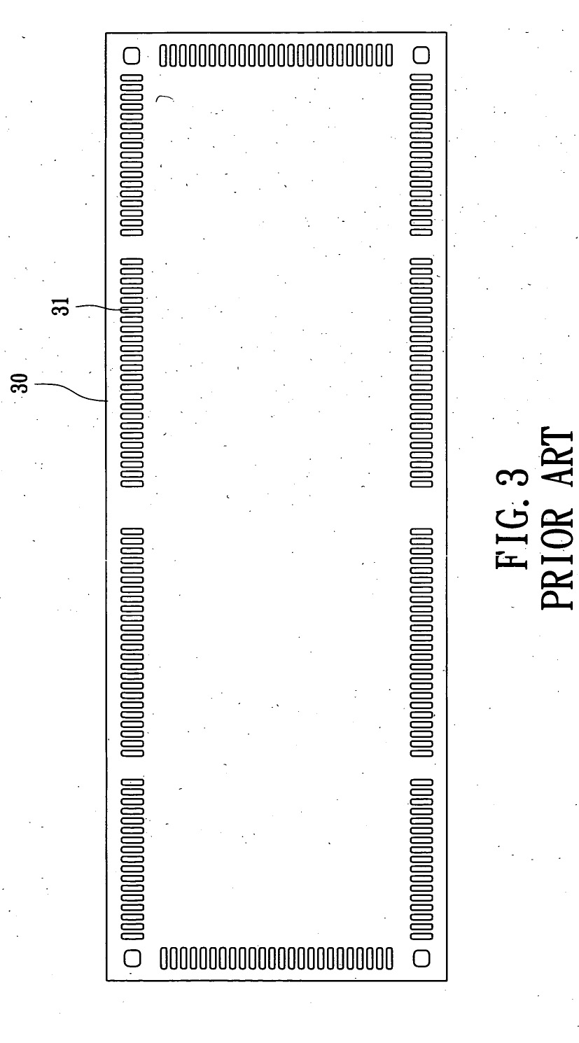

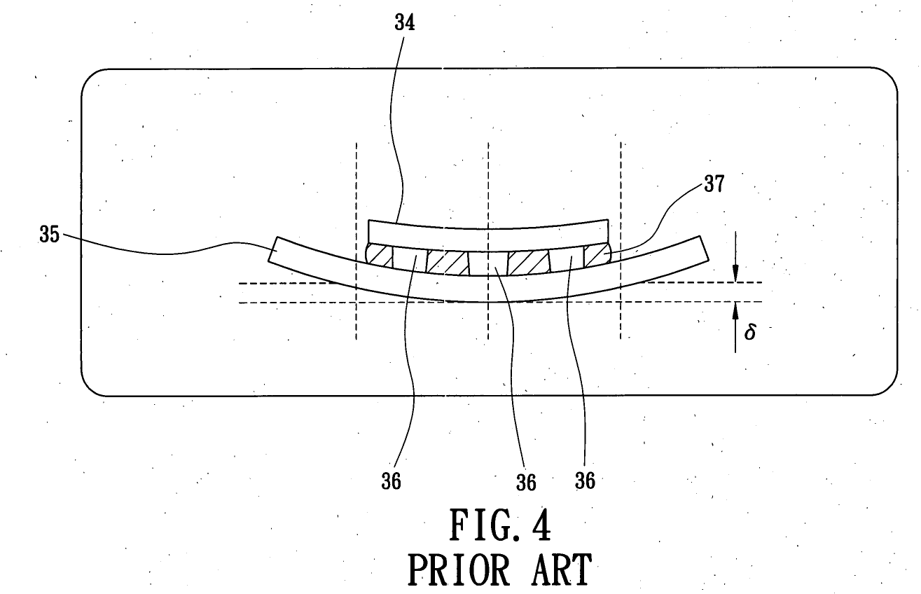

### DETAILED DESCRIPTION OF THE PREFERRED EMBODIMENTS

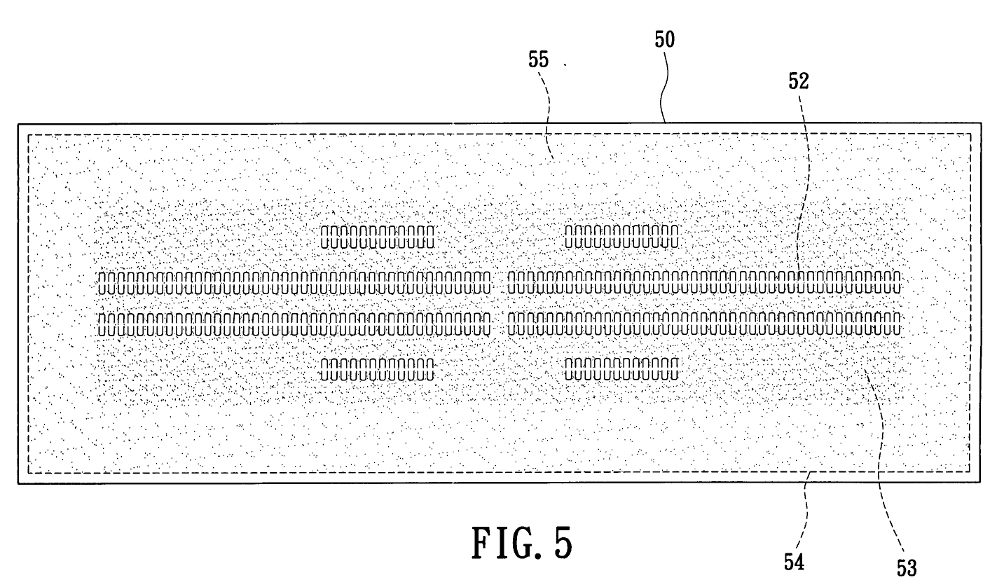

Reference is made to FIG. 5, which is 3a schematic view showing the structure of the flip chip device of the present invention. Included are a substrate 54, a chip 50 which has a surface and a plurality of compliant bumps 52 thereon, the compliant bumps 52 are centrally disposed on the center of the chip 50 for electrically connecting to the chip 50 and the substrate 54, and an adhesive 53 daubed on a joint area of the substrate 54 and the chip 50 for jointing the substrate 54 and the chip 50. The flip chip device further comprises a non-conductive adhesive 55 daubed on a non-conductive joint area of the substrate 54 and the chip 50 so as to reduce the amount of conductive adhesive required, thereby reducing costs. Therein, the adhesive 53 is comprised of an anisotropic conductive film, a UV glue, or a non-conductive glue; the substrate is an organic substrate, a ceramic substrate, a glass substrate, a silicon substrate, or a GaAs substrate.

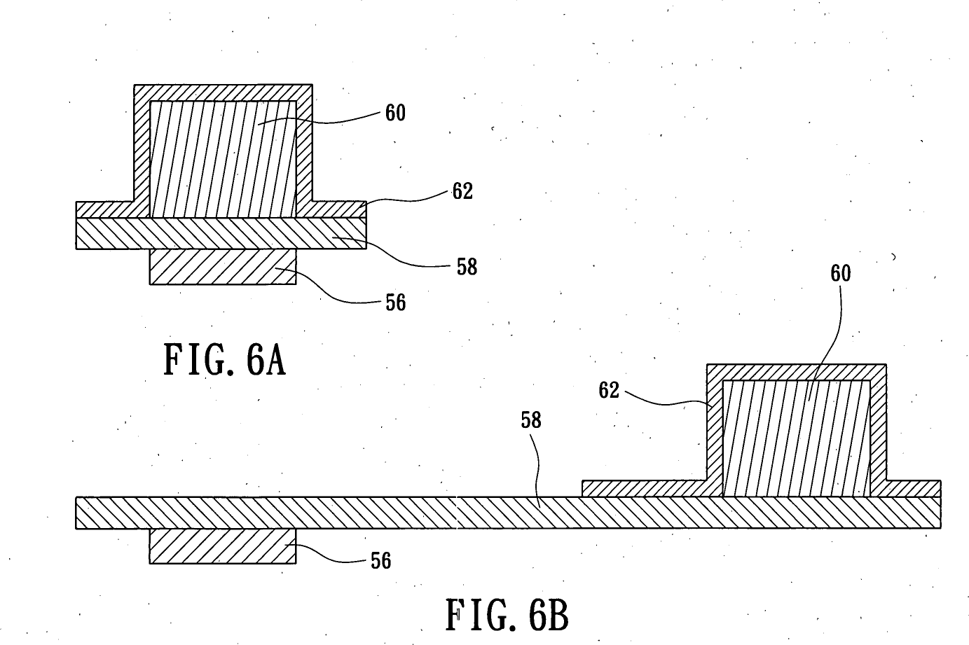

Reference is made to FIG. 6A and FIG. 6B which are schematic views showing the structures of the compliant bumps of the present invention. The compliant bumps are formed with a lower metal layer 58, a bump 60, and a upper metal layer 62. The upper metal layer 62 covers two opposite side surfaces of the bump 60 to connect with the lower metal layer 58 for electrically connecting the substrate 54 and the electrodes 56 of the chip 50, and the other two opposite side surfaces that don't cover the metal layer 62 block the lateral electrical connection of the adjacent compliant bumps 52 so that the compliant bumps 52 centrally disposed on the center of the chip 50 will not short. Therein, the lower metal layer 58 is a Ti—W metal layer, the bump 60 is formed with a polymer, and the upper metal layer 62 is an Au metal layer.

By extending the lower metal layer 58 to change the position of the compliant bumps 52, the compliant bumps 52 are centrally disposed on the chip 50 without changing the electrical characteristics and the wiring arrangement of the chip 50. The manufacture of the bump 60 can also use the process of producing the compliant bumps, without changing the numbers of masks or the numbers of processes needed, as long as the lower metal layer 58 is extended to move the compliant bumps 52 to the center of the chip 50.

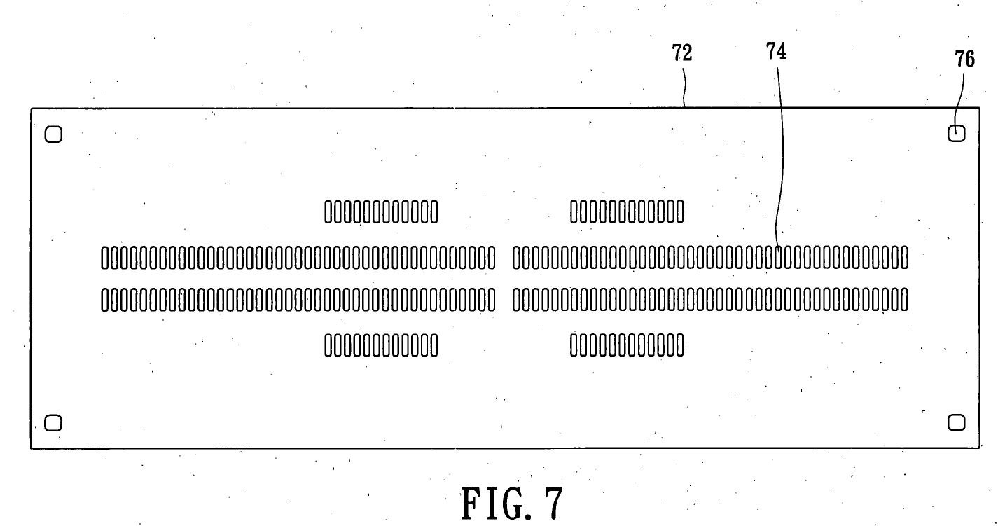

Reference is made to FIG. 7, which is a schematic view showing the second embodiment of the compliant bumps disposed on the chip of the present invention. Included are a chip 72 which has a surface and a plurality of compliant bumps 74 thereon, the compliant bumps 74 are centrally disposed on the center of the chip 72, and a plurality of non-connecting electrically compliant bumps 76 are disposed in a corner of the chip 72 for maintaining the parallel of the joint.

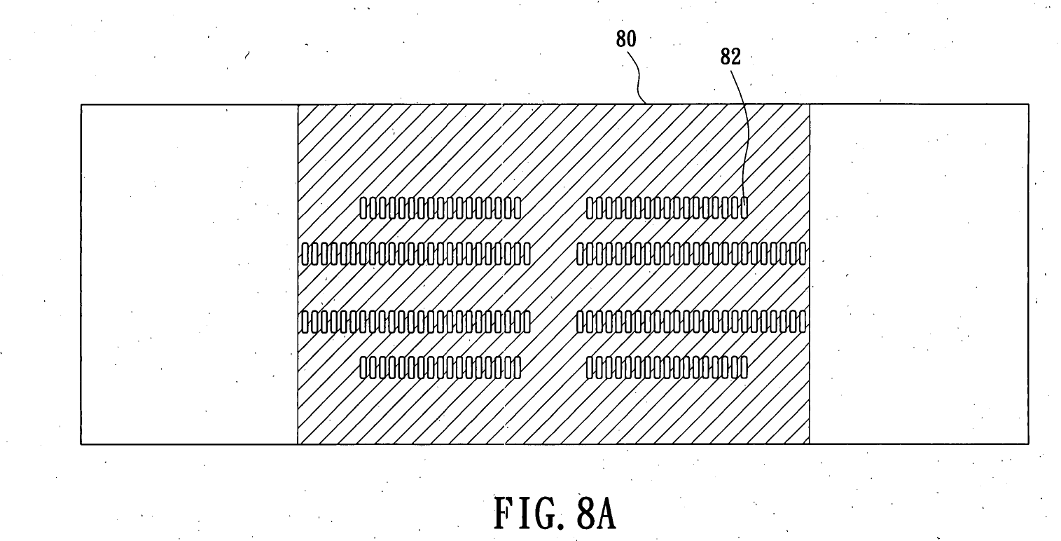

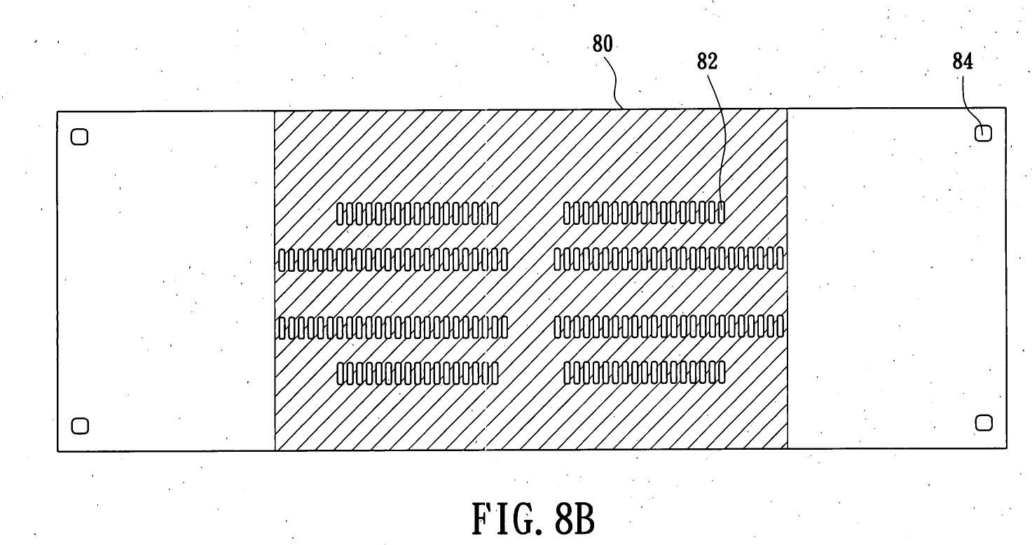

Reference is made to FIG. 8A, which is a schematic view showing the third embodiment of the compliant bumps disposed on the chip of the present invention. Included is a chip 80 and a plurality of compliant bumps 82 disposed on an area equidistant from the second sides of the chip 80.

Reference is made to FIG. 8B, which is a schematic view showing the fourth embodiment of the compliant bumps disposed on the chip of the present invention. Included is a chip 80 and a plurality of compliant bumps 82 disposed on an area equidistant from the second sides of the chip 80, and a plurality of non-connecting electrically compliant bumps 84 that are disposed in a corner of the chip 80 for maintaining the parallel of the joint.

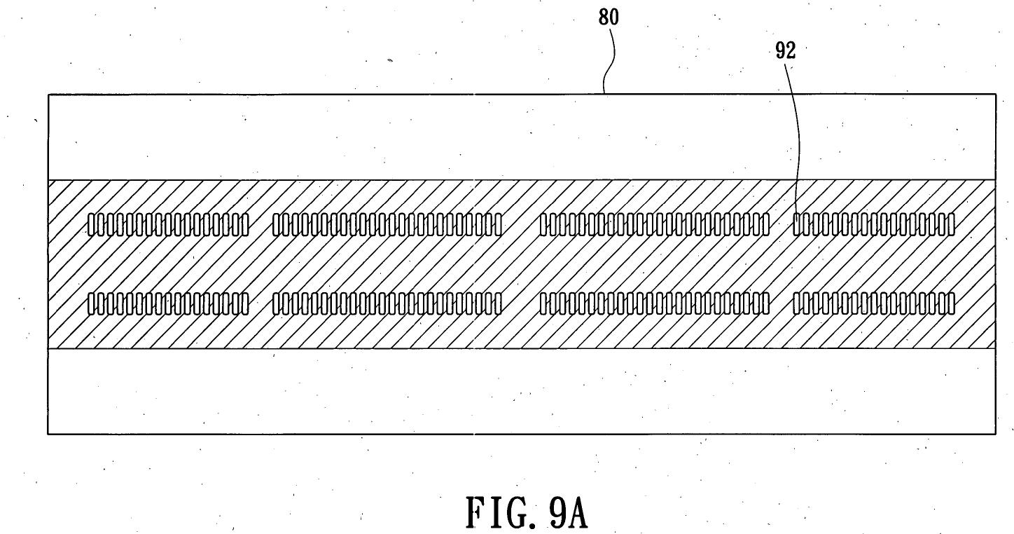

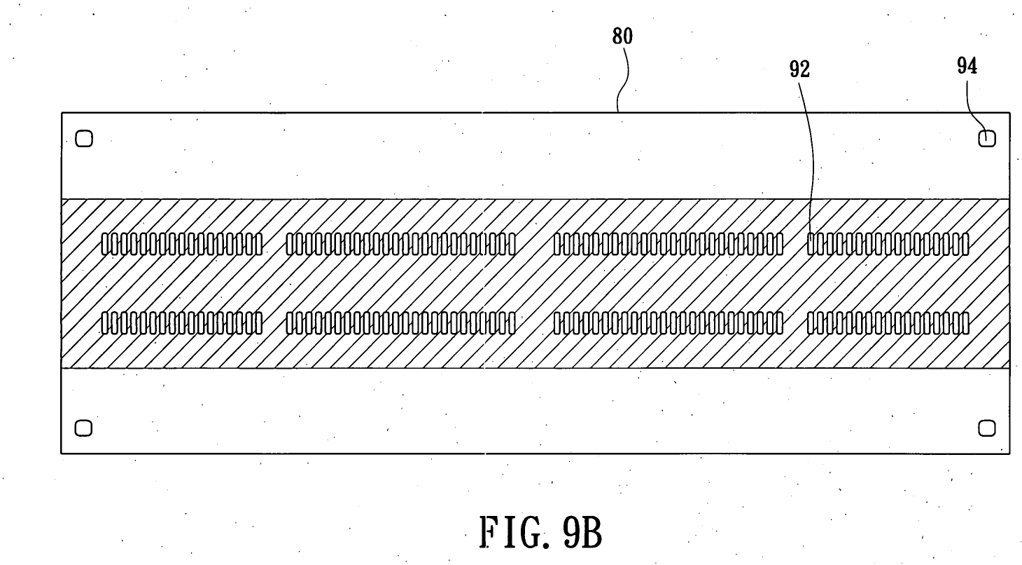

Reference is made to FIG. 9A, which is a schematic view showing the fifth embodiment of the compliant bumps disposed on the chip of the present invention. Included is a chip 80 and a plurality of compliant bumps 92 disposed on an area equidistant from the first sides of the chip 80.

Reference is made to FIG. 9B, which is a schematic view showing the sixth embodiment of the compliant bumps disposed on the chip of the present invention. Included is a chip 80 and a plurality of compliant bumps 92 disposed on an area equidistant from the first sides of the chip 80, and a plurality of non-connecting electrically compliant bumps 94 disposed in a corner of the chip 80 for maintaining the parallel of the joint.

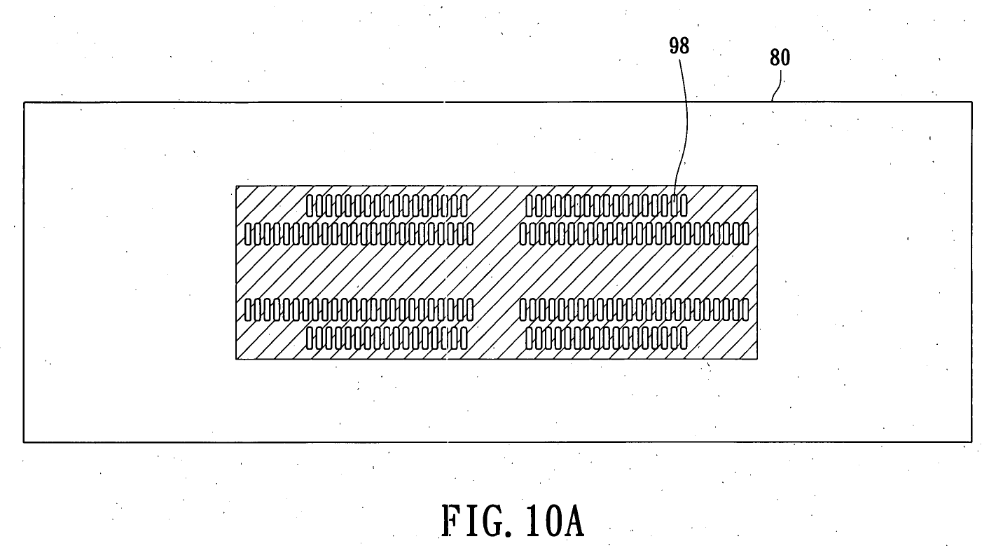

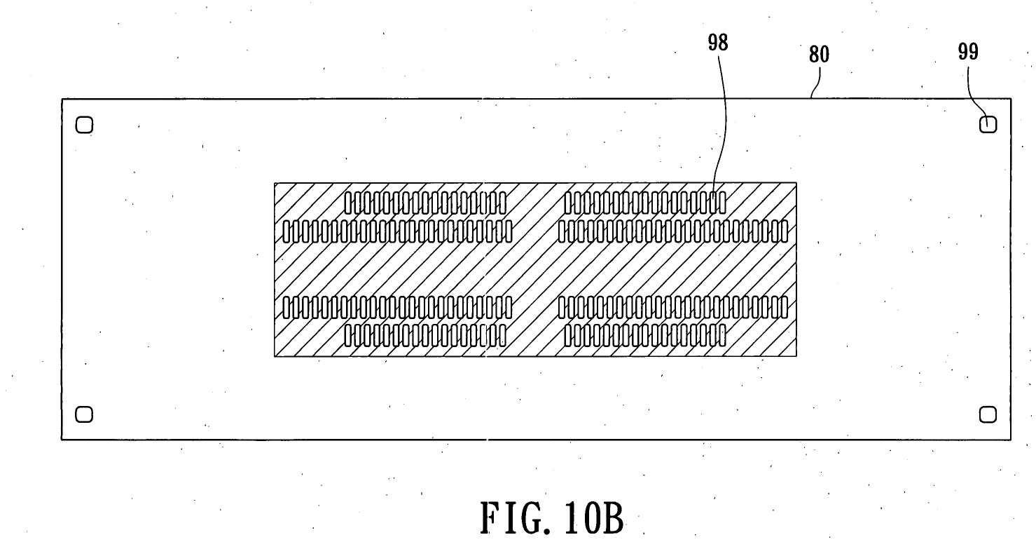

Reference is made to FIG. 10A, which is a schematic view showing the seventh embodiment of the compliant bumps disposed on the chip of the present invention. Included is a chip 80 and a plurality of compliant bumps 98 centrally disposed on an area whose diagonal lines are half of the length of the chip 80.

Reference is made to FIG. 10B, which is a schematic view showing the eighth embodiment of the compliant bumps disposed on the chip of the present invention. Included is a chip 80 and a plurality of compliant bumps 98 centrally disposed on an area whose diagonal lines are half of the length of the chip 80, and a plurality of non-connecting electrically compliant bumps 99 that are disposed in a corner of the chip 80 for maintaining the parallel of the joint.

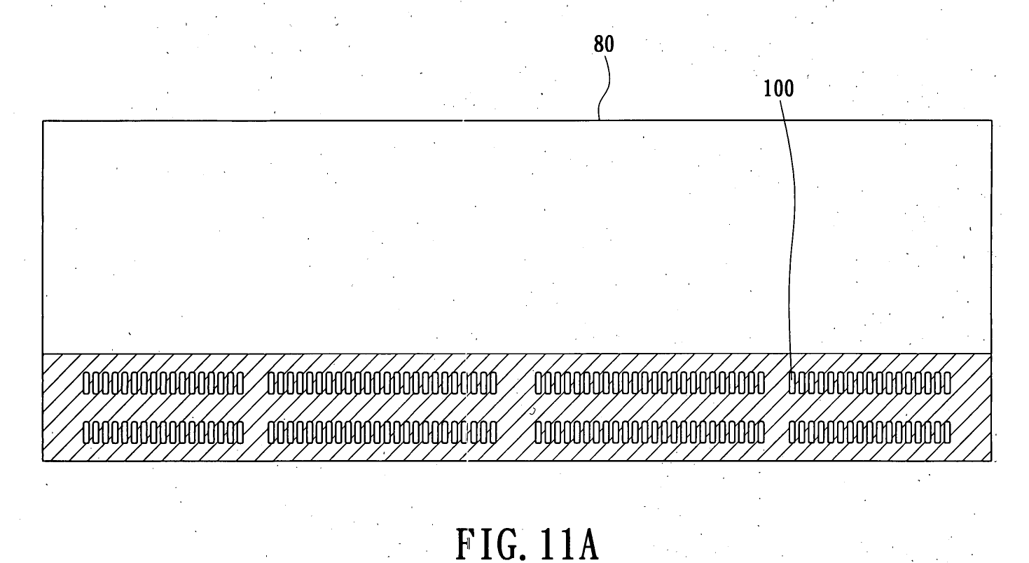

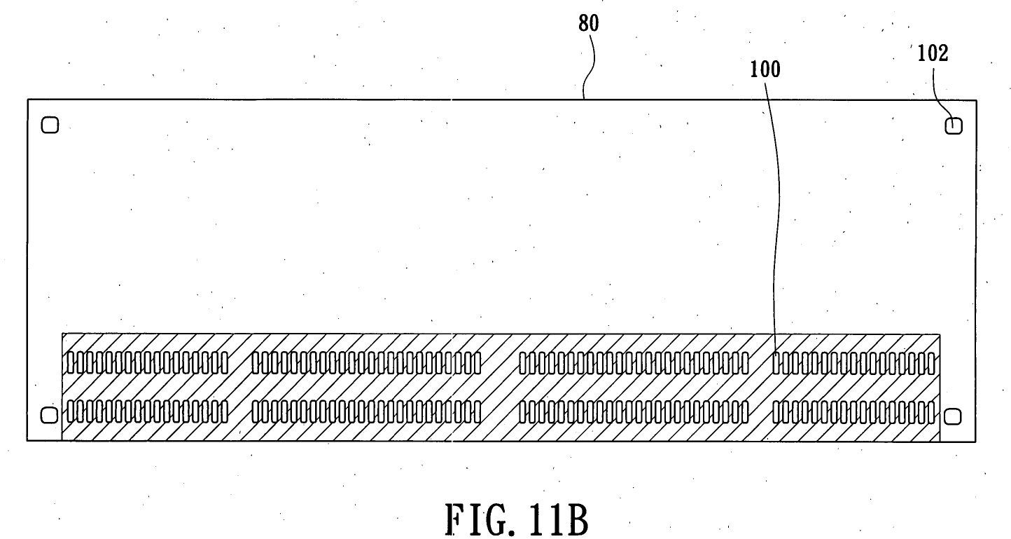

Reference is made to FIG. 11A, which is a schematic view showing the ninth embodiment of the compliant bumps disposed on the chip of the present invention. Included is a chip 80 and a plurality of compliant bumps 100 centrally disposed on one side of the chip 80.

Reference is made to FIG. 11B, which is a schematic view showing the tenth embodiment of the compliant bumps disposed on the chip of the present invention. Included is a chip 80 and a plurality of compliant bumps 100 centrally disposed on one side of the chip 80, and a plurality of non-connecting electrically compliant bumps 102 that are disposed in a corner of the chip 80 for maintaining the parallel of the joint.

There are characteristics and efficiencies of the present invention described below:

1. The bumps inwardly disposed on the center of the chip avoid the delamination of the adhesives because of the thermal stress, thereby maintaining the quality of the inner joints.

2. The joints of the bumps inwardly assembled on the center of the chip maintain the same resistance value of the joints.

3. The position of the bumps inwardly shrinks to extend the distance of air to the joints so as to prolong their reliability.

4. The non-conductive adhesive is used on a non-conductive joint area to reduce the costs added in the prior art due to the need for a conductive adhesive.

5. To avoid bending of the glass substrate due to adhesive bleeding.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are intended to be embraced within the scope of the invention as defined in the appended claims.

What is claimed is:

1. A flip chip device, comprising:
a substrate;
a plurality of chips having surfaces and a plurality of compliant bumps thereon, the compliant bumps are centrally disposed on the center of the chips for electrically connecting the chips and the substrate; and
an adhesive daubed on a joint area of the substrate and the chips for jointing the substrate and the chips.

2. A flip chip device as in claim 1, wherein the compliant bumps are formed with a lower metal layer, a bump, and a upper metal layer; the upper metal layer covers two opposite side surfaces of the bump to connect with the lower metal layer for electrically connecting the substrate and the chips, and another two opposite side surfaces without covering the metal layer for blocking lateral electrical connection of the adjacent compliant bumps so that the compliant bumps centrally disposed on the center of the chips will not short.

3. A flip chip device as in claim 2, wherein the lower metal layer is a Ti—W metal layer.

4. A flip chip device as in claim 2, wherein the bumps are formed with polymer.

5. A flip chip device as in claim 2, wherein the upper metal layer is an Au metal layer.

6. A flip chip device as in claim 1, further comprising:
a plurality of non-connecting electrically compliant bumps disposed in a corner of the chip for maintaining the parallel of the joint.

7. A flip chip device as in claim 1, wherein the substrate is an organic substrate, a ceramic substrate, a glass substrate, a silicon substrate or a GaAs substrate.

8. A flip chip device as in claim 1, wherein the adhesive is an anisotropic film, a UV glue, or a non-conductive glue.

9. A flip chip device as in claim 1, further comprising:
a non-conductive adhesive daubed on a non-conductive joint area of the substrate and the chips.

10. A flip chip device as in claim 1, wherein the compliant bumps are disposed on an area equidistant from the second sides of the chip.

11. A flip chip device as in claim 10, further comprising:
a plurality of non-connecting electrically compliant bumps disposed in a corner of the chip for maintaining the parallel of the joint.

12. A flip chip device as in claim 1, wherein the compliant bumps are centrally disposed on an area equidistant from the first sides of the chip.

13. A flip chip device as in claim 12, further comprising:
a plurality of non-connecting electrically compliant bumps disposed in a corner of the chip for maintaining the parallel of the joint.

14. A flip chip device as in claim 1, wherein the compliant bumps are centrally disposed on an area whose diagonal lines are half of the length of the chip.

15. A flip chip device as in claim 14, further comprising:
a plurality of non-connecting electrically compliant bumps disposed in a corner of the chip for maintaining the parallel of the joint.

16. A flip chip device as in claim 1, wherein the compliant bumps are centrally disposed on one side of the chip.

17. A flip chip device as in claim 14, further comprising:
a plurality of non-connecting electrically compliant bumps disposed in a corner of the chip for maintaining the parallel of the joint.
